(19) United States
(12) Patent Application Publication
(10) Pub. No.: US 2007/0235888 A1
(43) Pub. Date: Oct. 11, 2007

(54) FILM TYPE PACKAGE AND DISPLAY APPARATUS HAVING THE SAME

(76) Inventor: Nam-Jung Her, Suwon-si (KR)

Correspondence Address: F. CHAU & ASSOCIATES, LLC, 130 WOODBURY ROAD, WOODBURY, NY, 11797, US

(21) Appl. No.: 11/697,540

(22) Filed: Apr. 6, 2007

(30) Foreign Application Priority Data
Apr. 6, 2006 (KR) 2006-31474

(51) Int. Cl. H01L 23/52

(52) U.S. Cl. 257/784

(57) ABSTRACT

A film type package includes a base film, a driving integrated circuit mounted on the base film for inputting/outputting signals to/from external circuits, a plurality of signal lines formed on the base film for transmitting the signals between the external circuits and the driving integrated circuit, a plurality of bonding pads formed on the base film such that the plurality of signal lines are connected to the external circuits, wherein the plurality of bonding pads correspond to the plurality of signal lines, and a test line connected to the driving integrated circuit for transmitting test signals outputted from the driving integrated circuit, wherein the test line is spaced apart from an adjacent signal line among the plurality of signal lines by a predetermined distance.

### CROSS-REFERENCE TO RELATED APPLICATION

This application claims priority under 35 U.S.C. § 119 to Korean Patent Application No. 2006-31474, filed on Apr. 6, 2006, the entire contents of which are hereby incorporated by reference.

### BACKGROUND OF THE INVENTION

1. Technical Field

The present disclosure relates to a display device, and more particularly, to a film type package and a display device having the same.

2. Discussion of Related Art

In a display device, a driving integrated circuit such as a data driving unit or a gate driving unit is mounted on a base film. The driving integrated circuit can be formed in a film type package. The film type package can be electrically connected to a printed circuit board or a display panel using bonding pads so that signals are inputted/outputted therethrough.

The bonding pads of the film type package are connected to the printed circuit board or the display panel.

### SUMMARY OF THE INVENTION

An exemplary embodiment of the present invention provides a film type package that can be easily tested.

An exemplary embodiment of the present invention provides a display device having the film type package.

According to an exemplary embodiment of the present invention, a film type package includes a base film, a driving integrated circuit mounted on the base film for inputting/outputting signals to/from external circuits, a plurality of signal lines formed on the base film for transmitting the signals between the external circuits and the driving integrated circuit, a plurality of bonding pads formed on the base film such that the plurality of signal lines are connected to the external circuits, wherein the plurality of bonding pads correspond to the plurality of signal lines, and a test line connected to the driving integrated circuit for transmitting test signals outputted from the driving integrated circuit, wherein the test line is spaced apart from an adjacent signal line among the plurality of signal lines by a predetermined distance.

The plurality of bonding pads may include a first bonding pad and a second bonding pad, wherein the test line is formed adjacent to the first bonding pad.

The test signal can be a reference signal for testing an operating performance of the driving integrated circuit.

The film type package may further comprise a test pad integrally formed on an end of the test line.

A size of the first bonding pad adjacent to the test line can be smaller than a size of the second bonding pad.

A signal line corresponding to the first bonding pad adjacent to the test line may transmit a ground signal.

According to an exemplary embodiment of the present invention, a display device includes a printed circuit board mounting a controller outputting a control signal through a plurality of control lines, wherein a plurality of first bonding pads are formed corresponding to the plurality of control lines, a film type package including a plurality of driving signal lines transmitting driving signals, the film type package mounting a driving integrated circuit outputting the driving signal in response to the control signal and a plurality of second bonding pads corresponding to the respective driving signal lines, wherein the second bonding pads are bonded to the first bonding pads of the printed circuit board, and a display panel bonded to the film package, the display panel displaying an image in response to the driving signal, wherein the plurality of second bonding pads include a third bonding pad and a fourth bonding pad, and the test line is formed adjacent to the third bonding pad for transmitting a test signal outputted from the driving integrated circuit.

### BRIEF DESCRIPTION OF THE DRAWINGS

Exemplary embodiments of the present disclosure can be understood in more detail from the following description taken in conjunction with the accompanying drawings of which:

FIG. 1 is a plan view illustrating a film type package according to an exemplary embodiment of the present invention;

FIG. 2 is an enlarged plan view of the region A of FIG. 1;

FIG. 3 is a plan view illustrating a bonding structure between a printed circuit board and a film type package according to an exemplary embodiment of the present invention;

FIG. 4 is a plan view illustrating a method of testing a film type package according to an exemplary embodiment of the present invention; and

FIG. 5 is a plan view illustrating a display device having a film type package according to an exemplary embodiment of the present invention.

### DETAILED DESCRIPTION OF EXEMPLARY EMBODIMENTS

Exemplary embodiments of the present invention will be described in more detail with reference to the accompanying drawings. The present invention may, however, be embodied in many different forms and should not be construed as limited to the embodiments set forth herein. An additional test circuit is formed for an inspection process such as a design for test (DT) process at a designing stage in the manufacture of a semiconductor. The test circuit formed inside the semiconductor detects during the DFT process whether the semiconductor device operates without failure.

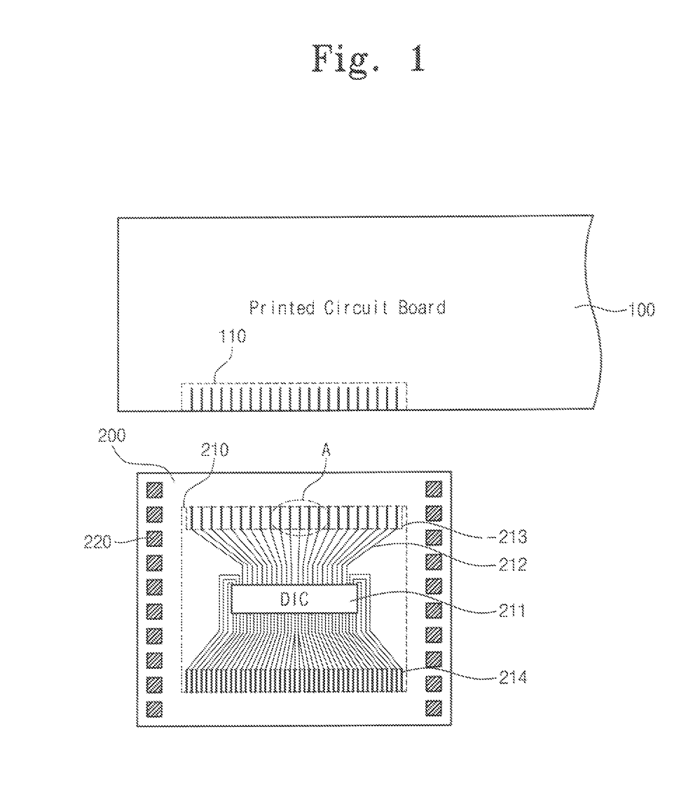

FIG. 1 is a plan view illustrating a film type package according to an exemplary embodiment of the present invention.

Referring to FIG. 1, a film type package 200 formed on a base film is cut along a cutting line 210, and is electrically connected to bonding pads 110 of a printed circuit board 100.

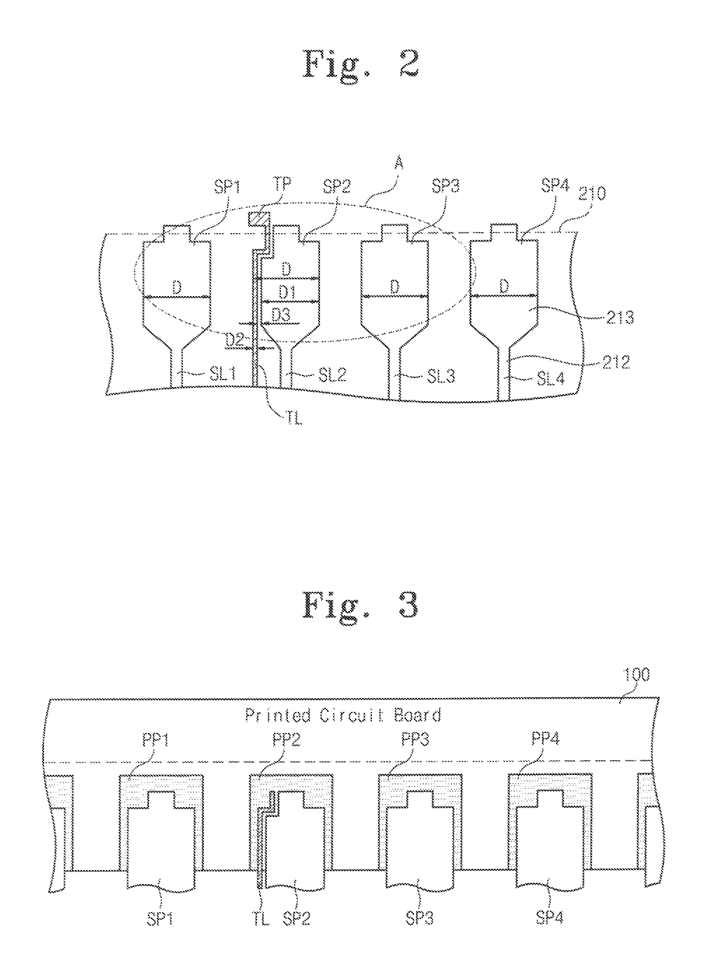

The film type package 200 includes a driving integrated circuit (DIC) 211, a plurality of signal lines 212, a test line TL (see FIG. 2), upper bonding pads 213 and lower bonding pads 214.

The driving integrated circuit 211 is mounted on the base film. The driving integrated circuit 211 includes an additional test circuit for an inspection process such as the DFT process at the designing stage of the driving integrated circuit 211. Respective terminals of the driving integrated circuit 211 are connected to a plurality of signal lines 212. The plurality of signal lines 212 transmit signals inputted/outputted to/from the driving integrated circuit 211. The test circuit in the driving integrated circuit 211 is connected to a test line TL through a test terminal.

The upper and lower bonding pads 213 and 214 of the film type package 200 are connected to the signal lines 212. The upper bonding pads 213 are electrically connected to bonding pads 110 of the printed circuit board 100, and the lower bonding pads 214 are bonded to, for example, a display panel.

At both left and right edges of the film type package 200, there are formed a plurality of sprocket holes 220. The sprocket holes 220 fix the film type package 200 to a predetermined location in the manufacturing process of the film type package 200. The film type package 200 is cut along the cutting line 210 in an assembly process so that the sprocket holes 220 are not included in the film type package 200.

FIG. 2 is an enlarged plan view of the region A of FIG. 1.

Referring to FIG. 2, the plurality of signal lines 212 are formed on the base film, and one end of each signal line 212 is electrically connected to each of the upper bonding pads 213.

A first signal bonding pad SP1 of the upper bonding pads 213 is electrically connected to a first signal line SL1 of the signal lines 212, and a second signal bonding pad SP2 is electrically connected to a second signal line SL2. A third signal bonding pad SP3 is electrically connected to a third signal line SL3, and a fourth signal bonding pad SP4 is electrically connected to fourth signal line SL4.

To increase the bonding force between the printed circuit board 100 and the bonding pad 110, the first signal bonding pad SP1 has a greater width D than that of the first signal line SL1. The third signal bonding pad SP3 and the fourth signal bonding pad SP4 have a predetermined width D.

The second signal bonding pad SP2 and the test line TL are formed within a distance corresponding to the width D of one signal bonding pad 213. The second signal bonding pad SP2 and the test line TL are spaced apart from each other by a predetermined distance D3. That is, a width D1 of the second signal bonding pad SP2 is smaller than the width D of one signal bonding pad 213. The summation of the width D1 of the second signal bonding pad SP2, the width D2 of the test line TL, and a gap D3 between the test line TL and the second signal bonding pad SP2 are equal to the width D of one signal bonding pad 213.

A test signal, which is outputted from the test circuit (not shown) in the driving integrated circuit 211, is transmitted through the test line TL having a predetermined width D2. The test signal detects whether there is an error in the driving integrated circuit 211. The test signal is used in testing the operating performance of the driving integrated circuit 211. A test apparatus (not shown) detects the test signal transmitted through the test line TL using, for example, a probe to determine whether the driving integrated circuit 211 operates without failure.

When determining whether the driving integrated circuit 211 operates without failure, a test pad TP having a large area is used for detecting the test signal using a probe. The test pad TP is electrically connected to one end of the test line TL, and is formed outside the cutting line 210. The film type package 200 is cut along the cutting line 210 in an assembly process so that the test pad TP is not included in the film type package 200.

FIG. 3 is a plan view illustrating a bonding structure between a printed circuit board and a film type package according to an exemplary embodiment of the present invention.

Referring to FIG. 3, a first bonding pad PP1 among the bonding pads 220 of the printed circuit board 100 is bonded to the first signal bonding pad SP1 of the film type package 200. A second bonding pad PP2 is bonded to the second signal bonding pad SP2. A third bonding pad PP3 is bonded to the third signal bonding pad SP3 of the film type package 200. A fourth bonding pad PP4 is bonded to the fourth signal bonding pad SP4.

The bonding pads 110 of the printed circuit board 100 and the upper bonding pads 213 of the film type package 200 contact each other using, for example, an anisotropic conductive film (ACF). The ACF can have a shape similar to a double sided tape. A bonding component used in the ACF is melt when applying a high pressure using a bar with a high temperature to a region where the ACF is formed. Accordingly, the bonding pads 110 of the printed circuit board 100 and upper bonding pads 213 of the film type package 200 are electrically connected to each other.

The gap between the test line TL of the film type package 200 and the second signal bonding pad SP2 is small. The test line TL and the second signal bonding pad SP2 are electrically connected to the second bonding pad PP2 of the printed circuit board 100. Therefore, the test line TL is electrically connected to the second signal bonding pad SP2 when thermally compressing the printed circuit board 100 and the film type package 200.

For example, the second signal line SL2 connected to the second signal bonding pad SP2 may be signal line transmitting a ground signal. Therefore, by the thermal compression of the printed circuit board 100 and the film type package 200, the test line TL is electrically connected to the second signal bonding pad SP2 for transmitting the ground signal. Thus, after bonding the printed circuit board 100 and the film type package 200, a specific signal is transmitted through the test line so that it is possible to remove an erroneous operation of the device having the printed circuit board 100 and the film type package 200.

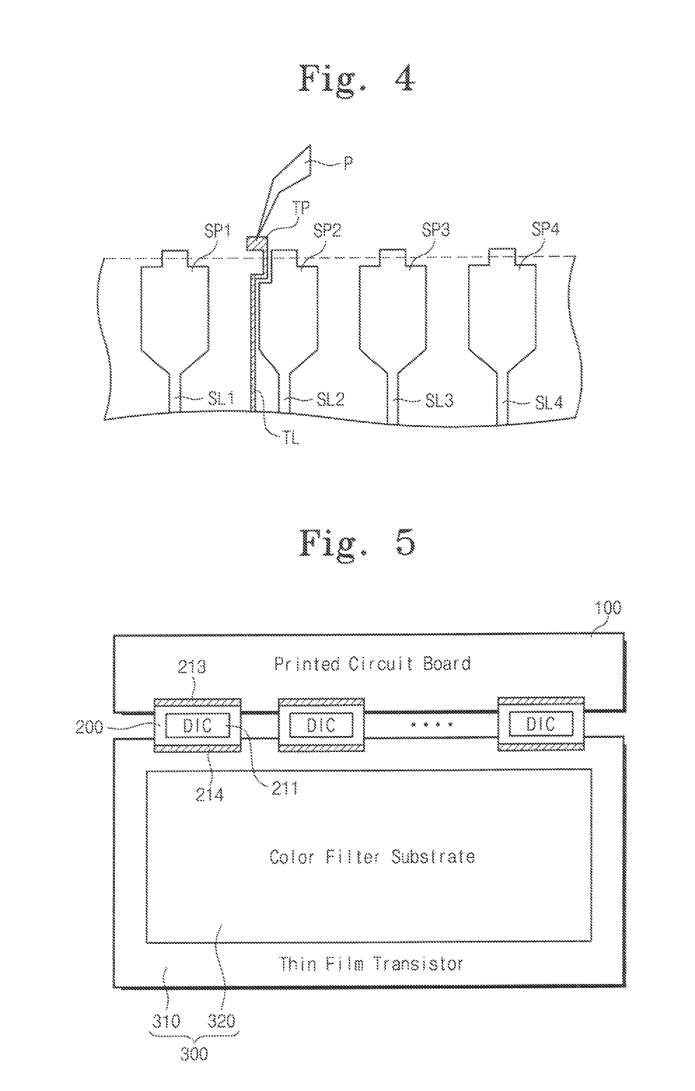

FIG. 4 is a plan view illustrating a method of testing a film type package according to an exemplary embodiment of the present invention.

Referring to FIG. 4, after forming the driving integrated circuit 211, the signal lines 212 and the upper bonding pads 213 on the base film, the operating performance of the driving integrated circuit 211 may be tested by detecting the test signal transmitted through the test line TL.

A test apparatus (not shown) detects the test signal by contacting the probe P with the test pad TP formed outside the cutting line 210. Thereafter, the test apparatus tests the operating performance of the driving integrated circuit 211 based on a preset reference signal.

FIG. 5 is a plan view illustrating a display device having a film type package according to an exemplary embodiment of the present invention.

Referring to FIG. 5, the display device includes the printed circuit board 100, the film type package 200 and a display panel 300.

In the printed circuit board 100, there are mounted various kinds of parts such as, for example, a controller (not shown) or a driving voltage generator (not shown). The controller of the printed circuit board 100 outputs a control signal. The driving voltage generator outputs voltages used for the operation of the display device. The voltages can be, for example, power voltage, gate-on voltage and gate-off voltage.

The upper bonding pads 213 of the film type package 200 where the driving integrated circuit is mounted are electrically connected to the bonding pads 110 of the printed circuit board 100. The lower bonding pads 214 of the film type package 200 are electrically connected to the display panel 300. The film type package 200 and the printed circuit board 100 contact each other using the ACF. The film type package 200 and the display panel 300 contact each other using the ACF.

The driving integrated circuit 211 of the film type package 200 includes an additional test circuit for an inspection process such as a DFT process at a designing stage. The test circuit in the driving integrated circuit 211 is electrically connected to the test line TL formed on the film type package 200 through the test terminal. In a region where one of the bonding pads of the film type package 200 is formed, both the test line TL and one signal bonding pad corresponding to a predetermined signal line are formed together. Accordingly, even after packaging the film type package 200, it is possible to test the operating performance of the driving integrated circuit 211.

The display panel 300, for example, comprises a liquid crystal display (LCD) panel in an exemplary embodiment of the present invention. The display panel 300 includes a thin film transistor (TFT) substrate 310, a color filter substrate 320, and a liquid crystal (not shown).

The TFT substrate 310 has a plurality of TFTs in a matrix on a glass substrate. One end of the film type package 200 is bonded to the TFT substrate 310.

The color filter substrate 320 is formed opposite to the TFT substrate 310 with respect to a liquid crystal layer formed therebetween. On the color filter substrate 320, there are formed red (R), green (G), and blue (B) pixels providing respective colors when light generated from a backlight passes therethrough.

The liquid crystal whose light transmissivity is varied with the intensity of electric field generated between a pixel electrode and a common electrode, is injected between the TFT substrate 310 and the color filter substrate 320. Therefore, a desired image can be displayed on the display panel 300.

According to an exemplary embodiment of the present invention, the test circuit of the driving integrated circuit mounted on the film type package is electrically connected to the test line formed on the film type package through the test terminal. Both the test line TL and one signal bonding pad corresponding to a predetermined signal line are formed adjacent to each other.

Accordingly, the operating performance of the driving integrated circuit can be tested through the test line even after the packaging process of the film type package is completed.

Although exemplary embodiments have been described with reference to the accompanying drawings, it is to be understood that the present invention is not limited to these precise embodiments but various changes and modifications can be made by one skilled in the art without departing from the spirit and scope of the present invention. All such changes and modifications are intended to be included within the scope of the invention as defined by the appended claims.

What is claimed is:

1. A film type package comprising:
a base film;
a driving integrated circuit mounted on the base film for inputting/outputting signals to/from external circuits;
a plurality of signal lines formed on the base film for transmitting the signals between the external circuits and the driving integrated circuit;
a plurality of bonding pads formed on the base film such that the plurality of signal lines are connected to the external circuits, wherein the plurality of bonding pads correspond to the plurality of signal lines; and
a test line connected to the driving integrated circuit for transmitting test signals outputted from the driving integrated circuit, wherein the test line is spaced apart from an adjacent signal line among the plurality of signal lines by a predetermined distance.

2. The film type package of claim 1, wherein the plurality of bonding pads include a first bonding pad and a second bonding pad, wherein the test line is formed adjacent to the first bonding pad.

3. The film type package of claim 2, wherein the test signal is a reference signal for testing an operating performance of the driving integrated circuit.

4. The film type package of claim 3, further comprising a test pad integrally formed on an end of the test line.

5. The film type package of claim 2, wherein a size of the first bonding pad adjacent to the test line is smaller than a size of the second bonding pad.

6. The film type package of claim 5, wherein a signal line corresponding to the first bonding pad adjacent to the test line transmits a ground signal.

7. A display device comprising:
a printed circuit board mounting a controller outputting a control signal through a plurality of control lines, wherein a plurality of first bonding pads are formed corresponding to the plurality of control lines;
a film type package including a plurality of driving signal lines transmitting driving signals, the film type package mounting a driving integrated circuit outputting the driving signal in response to the control signal and a plurality of second bonding pads corresponding to the respective driving signal lines, wherein the second bonding pads are bonded to the first bonding pads of the printed circuit board; and
a display panel bonded to the film package, the display panel displaying an image in response to the driving signal,
wherein the plurality of second bonding pads include a third bonding pad and a fourth bonding pad, and the test line is formed adjacent to the third bonding pad for transmitting a test signal outputted from the driving integrated circuit.

8. The display device of claim 7, wherein the test signal is a reference signal for testing an operating performance of the driving integrated circuit.

9. The display device of claim 8, wherein the film package further comprises a test pad integrally formed on an end of the test line.

10. The display device of claim 7, wherein a size of the third bonding pad is smaller than that of the fourth bonding pad.

11. The display device of claim 10, wherein the driving signal line corresponding to the third bonding pad adjacent to the test line transmits a ground signal from the driving integrated circuit.

12. The display device of claim 11, wherein the test line is electrically connected to the third bonding pad adjacent to the test line.
